(19) United States
(12) Patent Application Publication
(10) Pub. No.: US 2016/0161650 A1
(43) Pub. Date: Jun. 9, 2016

(54) DISPLAYS WITH SELECTIVE REFLECTORS AND COLOR CONVERSION MATERIAL

(71) Applicant: Pixtronix, Inc., San Diego, CA (US)

(72) Inventors: Gianni Taraschi, Arlington, MA (US); Edward Buckley, Melrose, MA (US); Nikolay Nemchuk, North Andover, MA (US); James Eakin, Worcester, MA (US); Fahri Yaras, Chelsea, MA (US)

(21) Appl. No.: 14/562,173

(22) Filed: Dec. 5, 2014

(51) Int. Cl. G02B 5/28; B81B 7/02; G02B 26/02; F21V 8/00; G02F 1/1335

(52) U.S. Cl. CPC G02B 5/28; G02B 6/0066; G02F 1/133514; G02B 26/02; B81B 7/02; B81B 2201/047; G02F 2001/133521

(57) ABSTRACT

This disclosure provides systems, methods and apparatus for image displays incorporating color selective reflectors. The display apparatus includes a substantially monochromatic light source capable of outputting a substantially monochromatic light. The display apparatus incorporates a color conversion material capable of converting at least a portion of the substantially monochromatic light output by the substantially monochromatic light source into light associated with at least one subfield color. The display device also includes a plurality of pixels, each pixel including at least two color-selective reflectors, each color-selective reflector being capable of passing light of a respective subfield color and reflecting light associated with at least two other subfield colors.

### TECHNICAL FIELD

This disclosure relates to the field of displays, and in particular, to image formation processes used by displays.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, or other micromachining processes that etch away parts of substrates or deposited material layers, or that add layers to form electrical and electromechanical devices.

EMS-based display devices can include display elements that modulate light by selectively moving a light blocking component into and out of an optical path through an aperture defined through a light blocking layer. Doing so selectively passes light from a backlight or reflects light from the ambient or a front light to form an image.

### SUMMARY

The systems, methods and devices of this disclosure each have several innovative aspects, no single one of which is solely responsible for the desirable attributes disclosed herein.

One innovative aspect of the subject matter described in this disclosure can be implemented in an apparatus including a substantially monochromatic light source, a color conversion material, and a plurality of pixels. The substantially monochromatic light source is capable of outputting substantially monochromatic light. The color conversion material is capable of converting at least a portion of the substantially monochromatic light output by the substantially monochromatic light source into light associated with at least one subfield color. Each of the plurality of pixels includes at least two color-selective reflectors. Each color-selective reflector is capable of passing light of a respective subfield color and reflecting light associated with at least two other subfield colors.

In some implementations, the display apparatus can further include a collimator capable of collimating light directed at the color-selective reflectors. In some implementations, the display apparatus can further include a light guide capable of guiding light output by the substantially monochromatic light source towards the display elements. The color conversion material can include a quantum dot film or a phosphor film. The color-selective reflectors can include distributed Bragg reflectors (DBRs) or cholesteric liquid crystals. In some implementations, the color-selective reflectors can include a substantially angle invariant color selective reflector. The light output by the substantially monochromatic light source can be a blue light or an ultra violet (UV) light.

In some implementations, each pixel includes a respective light modulator. The light modulators can be liquid crystal (LC) light modulators. In some implementations, the light modulators include micro-electromechanical system (MEMS) shutters. In some implementations, each light modulator includes multiple micro-electromechanical system (MEMS) shutters such that each MEMS shutter is associated with a respective color-selective reflector. In some other implementations, each light modulator includes a single MEMS shutter.

In some implementations, the display apparatus can further include a light blocking layer positioned between the pixels and the color conversion material. The light blocking layer defines a plurality of apertures such that each of the color-selective reflectors associated with the pixels is positioned in an optical path between an aperture and a light modulator. In some implementations, each pixel can further include a color filter associated with a respective color-selective reflector. In some implementations, each pixel can further include two other color-selective reflectors each of which is associated with a respective color conversion material.

Another innovative aspect of the subject matter described in this disclosure can be implemented in an apparatus including means for outputting substantially monochromatic light, color conversion means and a plurality of pixels. The color conversion means is capable of converting at least a portion of the substantially monochromatic light output by the means for outputting substantially monochromatic light into light associated with at least one subfield color. Each of the plurality of pixels includes at least two color-selective reflecting means. Each color-selective reflecting means is capable of passing light of a respective subfield color and reflecting light associated with at least two other subfield colors.

In some implementations, the display apparatus can further include collimating means for collimating light directed at the color-selective reflectors. In some implementations, the color-selective reflecting means can include a substantially angle invariant color selective reflecting means. The light output by the means for outputting the substantially monochromatic light can be a blue light or an ultra violet (UV) light.

In some implementations, each pixel includes a respective light modulating means. In some implementations, the display apparatus can further include light blocking means positioned between the pixels and the color conversion material. The light blocking means define a plurality of apertures such that each of the color-selective reflecting means associated with the pixels is positioned in an optical path between an aperture and the light modulating means associated with that pixel. In some implementations, each pixel can further include a color filter associated with a respective color-selective reflector. In some implementations, each pixel can further include color filtering means associated respective color-selective reflecting means.

Another innovative aspect of the subject matter described in this disclosure can be implemented as a method of displaying image data including generating, by a substantially monochromatic light source, substantially monochromatic light, converting, by a color conversion material, at least a portion of the substantially monochromatic light into light associated with at least one subfield color, and, at each of a plurality of pixels, selectively passing light of a respective subfield color and reflecting light associated with at least two other subfield colors by at least two color-selective reflectors.

In some implementations, the method can further include guiding the substantially monochromatic light towards display elements. In some implementations, the method can further include collimating light directed at the color-selective reflectors. In some implementations, the method can further include modulating light associated with each pixel based on the image data. In some implementations, the method can further include color filtering, at each pixel, light associated with a respective color-selective reflector by a color filter.

In some implementations, the substantially monochromatic light can have a full width at half maximum (FWHM) bandwidth of less than or equal to about 100 nanometers. In some implementations, the color of the light passed and reflected by the color selective reflectors can substantially independent of the angle at which the light is incident on the color selective reflectors.

Details of one or more implementations of the subject matter described in this disclosure are set forth in the accompanying drawings and the description below. Other features, aspects, and advantages will become apparent from the description, the drawings and the claims. Note that the relative dimensions of the following figures may not be drawn to scale.

### BRIEF DESCRIPTION OF THE DRAWINGS

FIG. 1A shows a schematic diagram of an example direct-view microelectromechanical systems (MEMS)-based display apparatus.

FIG. 1B shows a block diagram of an example host device.

FIGS. 2A and 2B show views of an example dual actuator shutter assembly.

FIG. 3A shows a cross sectional view of an example display module incorporating a color conversion material and color selective reflectors.

FIG. 3B shows a cross-sectional view of an example display module incorporating a color conversion material packaged with a substantially monochromatic light source and color selective reflectors.

FIG. 4A shows a simplified cross sectional view of a pixel of an example liquid crystal display (LCD) incorporating color conversion material and color selective reflectors.

FIG. 4B shows a simplified cross sectional view of a pixel of another example liquid crystal display (LCD) incorporating color conversion material and color selective reflectors.

FIG. 5A shows a two-dimensional (2-D) cross sectional view of an example MEMS-based display pixel incorporating color-selective reflectors.

FIG. 5B shows a three-dimensional (3-D) representation of the example MEMS-based display pixel in FIG. 2A.

FIG. 6 shows a two-dimensional (2-D) cross sectional view of another example MEMS-based display pixel incorporating color-selective reflectors.

FIGS. 7A-7D show cross sectional views of an example MEMS-based display module incorporating color conversion material and color selective reflectors.

FIG. 8 shows a cross sectional view of another example MEMS-based display module incorporating color conversion material and color selective reflectors

FIGS. 9A and 9B show system block diagrams of an example display device that includes a plurality of display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that is capable of displaying an image, whether in motion (such as video) or stationary (such as still images), and whether textual, graphical or pictorial. The concepts and examples provided in this disclosure may be applicable to a variety of displays, such as liquid crystal displays (LCDs), organic light-emitting diode (OLED) displays, field emission displays, and electromechanical systems (EMS) and microelectromechanical (MEMS)-based displays, in addition to displays incorporating features from one or more display technologies.

The described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, wearable devices, clocks, calculators, television monitors, flat panel displays, electronic reading devices (such as e-readers), computer monitors, auto displays (such as odometer and speedometer displays), cockpit controls or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, in addition to non-EMS applications), aesthetic structures (such as display of images on a piece of jewelry or clothing) and a variety of EMS devices.

The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

A display apparatus that outputs color subfields through color filters can improve its output efficiency by incorporating color selective reflectors between its light modulators and its backlight. The display apparatus can employ an architecture having a single light modulator per pixel or an architecture having a separate light modulator for each of multiple sub-pixels that make up a pixel. In displays with sub-pixel architectures, the color selective reflectors can pass light having the color associated with a given color subfield through a corresponding sub-pixel, allowing light associated with other color subfields to be recycled in the backlight and output through sub-pixels associated with other color subfields. For example, a display pixel can include red (R), green (G), and blue (B) sub-pixels, including red-pass, green-pass, and blue-pass reflective color filters, respectively. In some other implementations, the display pixel includes a single light modulator that modulates light for each color subfield according to a field sequential color (FSC) process. Suitable light modulators include, without limitation, liquid crystal light modulators and MEMS shutter-based light modulators. Example color selective reflectors include distributed Bragg reflectors, cholesteric liquid crystals, 2-D arrays of nano-pillars formed, for example, from silver or aluminum, photonic crystals, or other color-selective reflectors.

The efficiency of displays employing color selective reflectors can be further enhanced by incorporating a color conversion material into the backlight. In some implementations, the color conversion material can take the form of a quantum dot (QD) or phosphor film positioned in front of a light guide in the backlight. In some other implementations, the color conversion material can take the form of a suspension of quantum dots or phosphors positioned between the light guide and a light source. In some other implementations, the color conversion material can take the form of quantum dots or phosphors packaged with LED dies. The light source for the backlight is a substantially monochromatic light source having a wavelength selected to cause the color conversion material to generate at least two of the colors, such as red and green, used by the display as subfield colors in forming images. An example light source includes an LED die, such as a blue or ultraviolet (UV) LED die. In some implementations, the wavelength of the substantially monochromatic source is selected to correspond to a color that serves as a third subfield color used in generating images on the display, such as blue. In some other implementations, the wavelength of the substantially monochromatic light source is not intended to be output by the display, but instead used to generate subfield colors through interaction with the color conversion material. For example, the monochromatic light source can output ultraviolet light.

Particular implementations of the subject matter described in this disclosure can be implemented to realize one or more of the following potential advantages. Displays that generate the light for at least some of the subfield colors used for outputting images with color conversion materials can yield higher optical efficiency displays that can generate larger color gamuts. The light emitted by color conversion materials such as quantum dots and phosphors tend to have narrow spectral peaks (as compared to yellow phosphors, such a Yttrium aluminum garnet (YAG) based yellow phosphors), resulting in less light be lost through color filtering and purer subfield primary colors leading to larger color gamuts. The incorporation of color selective reflectors at each sub-pixel provides per-color light recycling to reduce optical losses typically incurred using absorptive color filters, further improving the optical efficiency of the display. The use of two-dimensional nano-arrays as color-selective reflectors or other incidence angle invariant color selective reflectors can help maintain high levels of color fidelity across larger viewing angles. Similar benefits can be achieved by incorporating a collimator between the color conversion material and the color-selective reflectors.

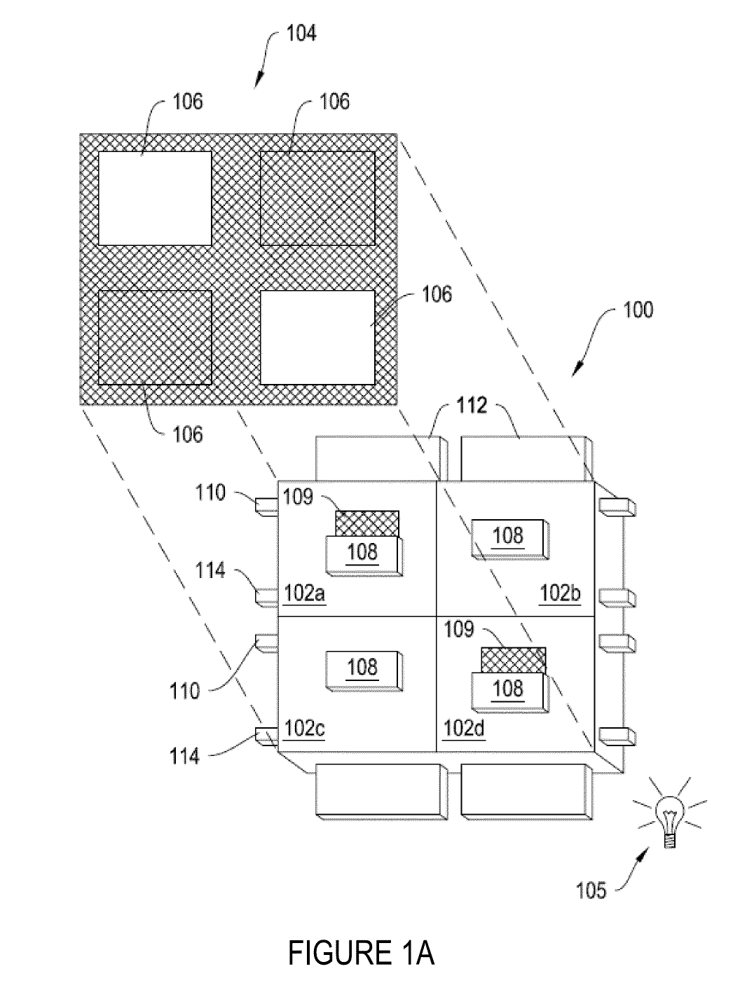

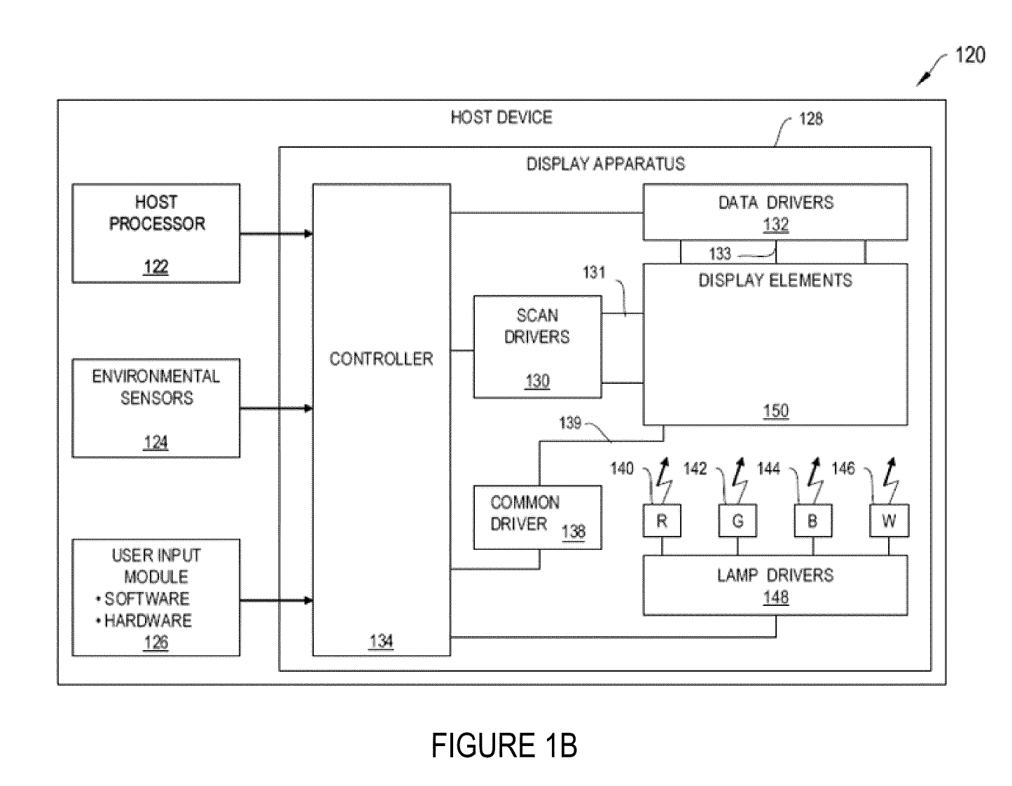

FIG. 1A shows a schematic diagram of an example direct-view MEMS-based display apparatus 100. The display apparatus 100 includes a plurality of light modulators 102a-102d (generally light modulators 102) arranged in rows and columns. In the display apparatus 100, the light modulators 102a and 102d are in the open state, allowing light to pass. The light modulators 102b and 102c are in the closed state, obstructing the passage of light. By selectively setting the states of the light modulators 102a-102d, the display apparatus 100 can be utilized to form an image 104 for a backlit display, if illuminated by a lamp or lamps 105. In another implementation, the apparatus 100 may form an image by reflection of ambient light originating from the front of the apparatus. In another implementation, the apparatus 100 may form an image by reflection of light from a lamp or lamps positioned in the front of the display, i.e., by use of a front light.

In some implementations, each light modulator 102 corresponds to a pixel 106 in the image 104. In some other implementations, the display apparatus 100 may utilize a plurality of light modulators to form a pixel 106 in the image 104. For example, the display apparatus 100 may include three color-specific light modulators 102. By selectively opening one or more of the color-specific light modulators 102 corresponding to a particular pixel 106, the display apparatus 100 can generate a color pixel 106 in the image 104. In another example, the display apparatus 100 includes two or more light modulators 102 per pixel 106 to provide a luminance level in an image 104. With respect to an image, a pixel corresponds to the smallest picture element defined by the resolution of image. With respect to structural components of the display apparatus 100, the term pixel refers to the combined mechanical and electrical components utilized to modulate the light that forms a single pixel of the image.

The display apparatus 100 is a direct-view display in that it may not include imaging optics typically found in projection applications. In a projection display, the image formed on the surface of the display apparatus is projected onto a screen or onto a wall. The display apparatus is substantially smaller than the projected image. In a direct view display, the image can be seen by looking directly at the display apparatus, which contains the light modulators and optionally a backlight or front light for enhancing brightness or contrast seen on the display.

Direct-view displays may operate in either a transmissive or reflective mode. In a transmissive display, the light modulators filter or selectively block light which originates from a lamp or lamps positioned behind the display. The light from the lamps is optionally injected into a lightguide or backlight so that each pixel can be uniformly illuminated. Transmissive direct-view displays are often built onto transparent substrates to facilitate a sandwich assembly arrangement where one substrate, containing the light modulators, is positioned over the backlight. In some implementations, the transparent substrate can be a glass substrate (sometimes referred to as a glass plate or panel), or a plastic substrate. The glass substrate may be or include, for example, a borosilicate glass, wine glass, fused silica, a soda lime glass, quartz, artificial quartz, Pyrex, or other suitable glass material.

Each light modulator 102 can include a shutter 108 and an aperture 109. To illuminate a pixel 106 in the image 104, the shutter 108 is positioned such that it allows light to pass through the aperture 109. To keep a pixel 106 unlit, the shutter 108 is positioned such that it obstructs the passage of light through the aperture 109. The aperture 109 is defined by an opening patterned through a reflective or light-absorbing material in each light modulator 102.

The display apparatus also includes a control matrix coupled to the substrate and to the light modulators for controlling the movement of the shutters. The control matrix includes a series of electrical interconnects (such as interconnects 110, 112 and 114), including at least one write-enable interconnect 110 (also referred to as a scan line interconnect) per row of pixels, one data interconnect 112 for each column of pixels, and one common interconnect 114 providing a common voltage to all pixels, or at least to pixels from both multiple columns and multiple rows in the display apparatus 100. In response to the application of an appropriate voltage (the write-enabling voltage, V_{WE}), the write-enable interconnect 110 for a given row of pixels prepares the pixels in the row to accept new shutter movement instructions. The data interconnects 112 communicate the new movement instructions in the form of data voltage pulses. The data voltage pulses applied to the data interconnects 112, in some implementations, directly contribute to an electrostatic movement of the shutters. In some other implementations, the data voltage pulses control switches, such as transistors or other non-linear circuit elements that control the application of separate drive voltages, which are typically higher in magnitude than the data voltages, to the light modulators 102. The application of these drive voltages results in the electrostatic driven movement of the shutters 108.

The control matrix also may include, without limitation, circuitry, such as a transistor and a capacitor associated with each shutter assembly. In some implementations, the gate of each transistor can be electrically connected to a scan line interconnect. In some implementations, the source of each transistor can be electrically connected to a corresponding data interconnect. In some implementations, the drain of each transistor may be electrically connected in parallel to an electrode of a corresponding capacitor and to an electrode of a corresponding actuator. In some implementations, the other electrode of the capacitor and the actuator associated with each shutter assembly may be connected to a common or ground potential. In some other implementations, the transistor can be replaced with a semiconducting diode, or a metal-insulator-metal switching element.

FIG. 1B shows a block diagram of an example host device 120 (i.e., cell phone, smart phone, PDA, MP3 player, tablet, e-reader, netbook, notebook, watch, wearable device, laptop, television, or other electronic device). The host device 120 includes a display apparatus 128 (such as the display apparatus 100 shown in FIG. 1A), a host processor 122, environmental sensors 124, a user input module 126, and a power source.

The display apparatus 128 includes a plurality of scan drivers 130 (also referred to as write enabling voltage sources), a plurality of data drivers 132 (also referred to as data voltage sources), a controller 134, common drivers 138, lamps 140-146, lamp drivers 148 and an array of display elements 150, such as the light modulators 102 shown in FIG. 1A. The scan drivers 130 apply write enabling voltages to scan line interconnects 131. The data drivers 132 apply data voltages to the data interconnects 133.

In some implementations of the display apparatus, the data drivers 132 are capable of providing analog data voltages to the array of display elements 150, especially where the luminance level of the image is to be derived in analog fashion. In analog operation, the display elements are designed such that when a range of intermediate voltages is applied through the data interconnects 133, there results a range of intermediate illumination states or luminance levels in the resulting image. In some other implementations, the data drivers 132 are capable of applying a reduced set, such as 2, 3 or 4, of digital voltage levels to the data interconnects 133. In implementations in which the display elements are shutter-based light modulators, such as the light modulators 102 shown in FIG. 1A, these voltage levels are designed to set, in digital fashion, an open state, a closed state, or other discrete state to each of the shutters 108. In some implementations, the drivers are capable of switching between analog and digital modes.

The scan drivers 130 and the data drivers 132 are connected to a digital controller circuit 134 (also referred to as the controller 134). The controller 134 sends data to the data drivers 132 in a mostly serial fashion, organized in sequences, which in some implementations may be predetermined, grouped by rows and by image frames. The data drivers 132 can include series-to-parallel data converters, level-shifting, and for some applications digital-to-analog voltage converters.

The display apparatus optionally includes a set of common drivers 138, also referred to as common voltage sources. In some implementations, the common drivers 138 provide a DC common potential to all display elements within the array 150 of display elements, for instance by supplying voltage to a series of common interconnects 139. In some other implementations, the common drivers 138, following commands from the controller 134, issue voltage pulses or signals to the array of display elements 150, for instance global actuation pulses which are capable of driving or initiating simultaneous actuation of all display elements in multiple rows and columns of the array.

Each of the drivers (such as scan drivers 130, data drivers 132 and common drivers 138) for different display functions can be time-synchronized by the controller 134. Timing commands from the controller 134 coordinate the illumination of red (R), green (G), blue (B) and white (W) lamps (140, 142, 144 and 146 respectively) via lamp drivers 148, the write-enabling and sequencing of specific rows within the array of display elements 150, the output of voltages from the data drivers 132, and the output of voltages that provide for display element actuation. In some implementations, the lamps are light emitting diodes (LEDs).

The controller 134 determines the sequencing or addressing scheme by which each of the display elements can be re-set to the illumination levels appropriate to a new image 104. New images 104 can be set at periodic intervals. For instance, for video displays, color images or frames of video are refreshed at frequencies ranging from 10 to 300 Hertz (Hz). In some implementations, the setting of an image frame to the array of display elements 150 is synchronized with the illumination of the lamps 140, 142, 144 and 146 such that alternate image frames are illuminated with an alternating series of colors, such as R, G, B and W. The image frames for each respective color are referred to as color subframes. In this method, referred to as the field sequential color method, if the color subframes are alternated at frequencies in excess of 20 Hz, the human visual system (HVS) will average the alternating frame images into the perception of an image having a broad and continuous range of colors. In some other implementations, the lamps can employ primary colors other than R, G, B and W. In some implementations, fewer than four, or more than four lamps with primary colors can be employed in the display apparatus 128.

In some implementations, where the display apparatus 128 is designed for the digital switching of shutters, such as the shutters 108 shown in FIG. 1A, between open and closed states, the controller 134 forms an image by the method of time division gray scale. In some other implementations, the display apparatus 128 can provide gray scale through the use of multiple display elements per pixel.

In some implementations, the data for an image state is loaded by the controller 134 to the array of display elements 150 by a sequential addressing of individual rows, also referred to as scan lines. For each row or scan line in the sequence, the scan driver 130 applies a write-enable voltage to the write enable interconnect 131 for that row of the array of display elements 150, and subsequently the data driver 132 supplies data voltages, corresponding to desired shutter states, for each column in the selected row of the array. This addressing process can repeat until data has been loaded for all rows in the array of display elements 150. In some implementations, the sequence of selected rows for data loading is linear, proceeding from top to bottom in the array of display elements 150. In some other implementations, the sequence of selected rows is pseudo-randomized, in order to mitigate potential visual artifacts. And in some other implementations, the sequencing is organized by blocks, where, for a block, the data for a certain fraction of the image is loaded to the array of display elements 150. For example, the sequence can be implemented to address every fifth row of the array of the display elements 150 in sequence.

In some implementations, the addressing process for loading image data to the array of display elements 150 is separated in time from the process of actuating the display elements. In such an implementation, the array of display elements 150 may include data memory elements for each display element, and the control matrix may include a global actuation interconnect for carrying trigger signals, from the common driver 138, to initiate simultaneous actuation of the display elements according to data stored in the memory elements.

In some implementations, the array of display elements 150 and the control matrix that controls the display elements may be arranged in configurations other than rectangular rows and columns. For example, the display elements can be arranged in hexagonal arrays or curvilinear rows and columns.

The host processor 122 generally controls the operations of the host device 120. For example, the host processor 122 may be a general or special purpose processor for controlling a portable electronic device. With respect to the display apparatus 128, included within the host device 120, the host processor 122 outputs image data as well as additional data about the host device 120. Such information may include data from environmental sensors 124, such as ambient light or temperature; information about the host device 120, including, for example, an operating mode of the host or the amount of power remaining in the host device's power source; information about the content of the image data; information about the type of image data; or instructions for the display apparatus 128 for use in selecting an imaging mode.

In some implementations, the user input module 126 enables the conveyance of personal preferences of a user to the controller 134, either directly, or via the host processor 122. In some implementations, the user input module 126 is controlled by software in which a user inputs personal preferences, for example, color, contrast, power, brightness, content, and other display settings and parameters preferences. In some other implementations, the user input module 126 is controlled by hardware in which a user inputs personal preferences. In some implementations, the user may input these preferences via voice commands, one or more buttons, switches or dials, or with touch-capability. The plurality of data inputs to the controller 134 direct the controller to provide data to the various drivers 130, 132, 138 and 148 which correspond to optimal imaging characteristics.

The environmental sensor module 124 also can be included as part of the host device 120. The environmental sensor module 124 can be capable of receiving data about the ambient environment, such as temperature and or ambient lighting conditions. The sensor module 124 can be programmed, for example, to distinguish whether the device is operating in an indoor or office environment versus an outdoor environment in bright daylight versus an outdoor environment at nighttime. The sensor module 124 communicates this information to the display controller 134, so that the controller 134 can optimize the viewing conditions in response to the ambient environment.

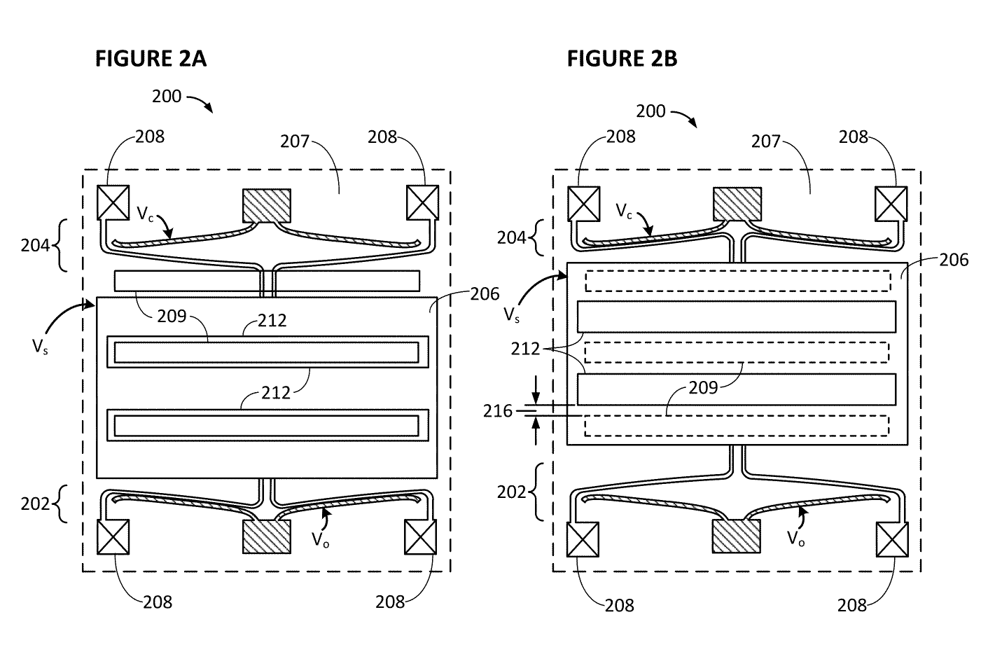

FIGS. 2A and 2B show views of an example dual actuator shutter assembly 200. The dual actuator shutter assembly 200, as depicted in FIG. 2A, is in an open state. FIG. 2B shows the dual actuator shutter assembly 200 in a closed state. The shutter assembly 200 includes actuators 202 and 204 on either side of a shutter 206. Each actuator 202 and 204 is independently controlled. A first actuator, a shutter-open actuator 202, serves to open the shutter 206. A second opposing actuator, the shutter-close actuator 204, serves to close the shutter 206. Each of the actuators 202 and 204 can be implemented as compliant beam electrode actuators. The actuators 202 and 204 open and close the shutter 206 by driving the shutter 206 substantially in a plane parallel to an aperture layer 207 over which the shutter is suspended. The shutter 206 is suspended a short distance over the aperture layer 207 by anchors 208 attached to the actuators 202 and 204. Having the actuators 202 and 204 attach to opposing ends of the shutter 206 along its axis of movement reduces out of plane motion of the shutter 206 and confines the motion substantially to a plane parallel to the substrate (not depicted).

In the depicted implementation, the shutter 206 includes two shutter apertures 212 through which light can pass. The aperture layer 207 includes a set of three apertures 209. In FIG. 2A, the shutter assembly 200 is in the open state and, as such, the shutter-open actuator 202 has been actuated, the shutter-close actuator 204 is in its relaxed position, and the centerlines of the shutter apertures 212 coincide with the centerlines of two of the aperture layer apertures 209. In FIG. 2B, the shutter assembly 200 has been moved to the closed state and, as such, the shutter-open actuator 202 is in its relaxed position, the shutter-close actuator 204 has been actuated, and the light blocking portions of the shutter 206 are now in position to block transmission of light through the apertures 209 (depicted as dotted lines).

Each aperture has at least one edge around its periphery. For example, the rectangular apertures 209 have four edges. In some implementations, in which circular, elliptical, oval, or other curved apertures are formed in the aperture layer 207, each aperture may have a single edge. In some other implementations, the apertures need not be separated or disjointed in the mathematical sense, but instead can be connected. That is to say, while portions or shaped sections of the aperture may maintain a correspondence to each shutter, several of these sections may be connected such that a single continuous perimeter of the aperture is shared by multiple shutters.

In order to allow light with a variety of exit angles to pass through the apertures 212 and 209 in the open state, the width or size of the shutter apertures 212 can be designed to be larger than a corresponding width or size of apertures 209 in the aperture layer 207. In order to effectively block light from escaping in the closed state, the light blocking portions of the shutter 206 can be designed to overlap the edges of the apertures 209. FIG. 2B shows an overlap 216, which in some implementations can be predefined, between the edge of light blocking portions in the shutter 206 and one edge of the aperture 209 formed in the aperture layer 207.

The electrostatic actuators 202 and 204 are designed so that their voltage-displacement behavior provides a bi-stable characteristic to the shutter assembly 200. For each of the shutter-open and shutter-close actuators, there exists a range of voltages below the actuation voltage, which if applied while that actuator is in the closed state (with the shutter being either open or closed), will hold the actuator closed and the shutter in position, even after a drive voltage is applied to the opposing actuator. The minimum voltage needed to maintain a shutter's position against such an opposing force is referred to as a maintenance voltage Vₘ.

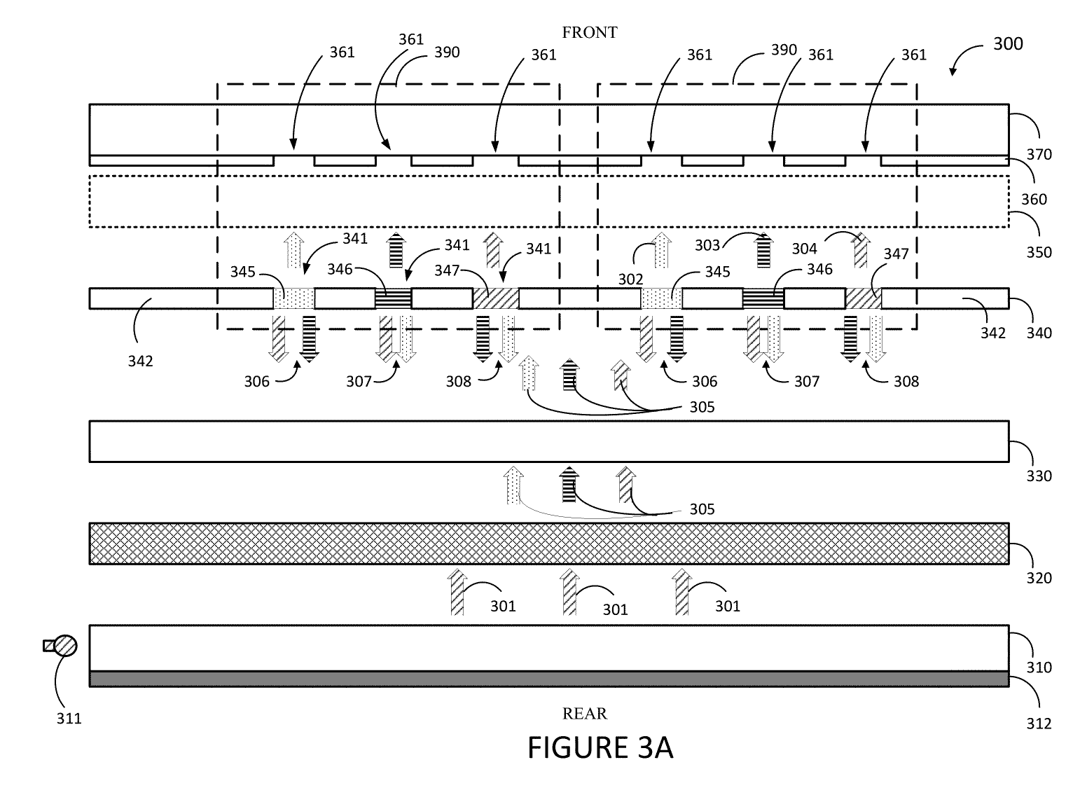

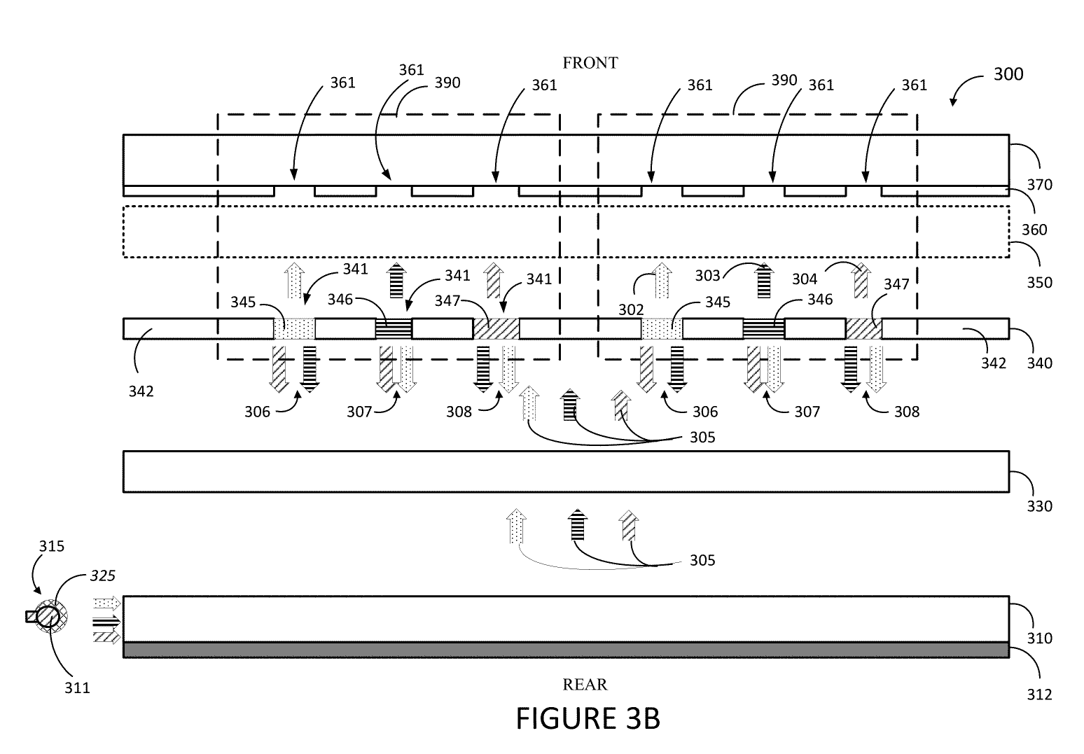

FIG. 3A shows a cross-sectional view of an example display module 300a incorporating a color conversion material and color selective reflectors. The display module 300a includes a substantially monochromatic light source 311, a light guide 310 having a reflective layer 312, a color conversion material 320, a collimator 330, a rear light blocking layer 340, a light modulating layer 350, a front aperture layer 360, and front substrate layer 370. The display module 300a also includes a plurality of pixels 390 distributed across the rear aperture layer 340, the light modulation layer 350, and the front aperture layer 360.

The display module 300a includes a substantially monochromatic light source 311 capable of outputting a substantially monochromatic light 301. In some implementations, a substantially monochromatic light source is a light source having a full width at half maximum (FWHM) bandwidth of less than or equal to about 100 nanometers (nm). In some implementations, a substantially monochromatic light source is a light source having a full width at half maximum (FWHM) bandwidth of less than or equal to 75 nanometers (nm). In some implementations, a substantially monochromatic light source is a light source having a full width at half maximum (FWHM) bandwidth of less than or equal to 50 nanometers (nm). In some implementations, a substantially monochromatic light source is a light source having a full width at half maximum (FWHM) bandwidth of less than or equal to 25 nanometers (nm). The substantially monochromatic light source 311 can be a substantially monochromatic light emitting diode (LED) die, a laser, or any other substantially monochromatic light source known to a person of ordinary skill in the art. The color of the substantially monochromatic light 301 can be blue, ultra violet (UV), or another light color. The substantially monochromatic light source 311 outputs the substantially monochromatic light into the light guide 310.

The light guide 310 is configured to distribute the substantially monochromatic light 301 substantially evenly across the display. In some implementations, the light reflecting layer 312 is capable of blocking light from passing through the back side of the light guide 310 and instead reflects incident light towards the front of the display module 300a. In some implementations, the use of the light reflecting layer 312 improves the optical efficiency of the display module 300a. In some implementations, the light guide 310 can further include a set of geometric light redirectors or prisms which re-direct light from the substantially monochromatic light source 311 towards the front of the display module 300a. The light redirectors can be molded into the plastic body of light guide 310 with shapes that can be triangular, trapezoidal, or curved in cross section. The density of the prisms can increase with distance from the substantially monochromatic light source 311.

The display module 300a includes a color conversion material 320 capable of converting the substantially monochromatic light 301 into light associated with a set of subfield colors used by the display module to output images. In some implementations, the subfield colors are red (R), green (G), and blue (B) 305. In some other implementations, the subfield colors can be any set of colors, which, when combined, form the white point of the color gamut of the display module 300a. In some implementations, one of the subfield colors is the same color as the light output by the substantially monochromatic light source 311. In such implementations, the color conversion material 320 converts a portion of the substantially monochromatic light 301 into light having the colors of other subfields. For ease of description, the following implementations will assume the display module employs R, G, and B as its subfield colors. A person having ordinary skill in the art would appreciate that the implementations can be adopted for use with different or additional subfield colors. In some implementations, the color conversion material 320 is arranged between the light guide 310 and the light modulation layer 350. In some implementations, a layer of the color conversion material 320 is arranged across all (or a portion of) the pixels 390 of the display module 300a. In some other implementations, the color conversion material 320 can be arranged between the substantially monochromatic light source 311 and the light guide 310. As such, light associated with the subfield colors 305 converted from the substantially monochromatic light 301 by the color conversion material 320 can be used to illuminate the pixels 390 of the display module 300a. In some implementations, the color conversion material 320 includes a quantum dot film. In some other implementations, the color conversion material 320 includes a phosphor film. In either case, the quantum dot film or the phosphor film is selected to have sharp spectral emission peaks at the subfield colors not output by the substantially monochromatic light source 311.

The display module 300a also includes a collimator 330 capable of collimating light exiting the color conversion material 320 directed towards the light modulation layer 350. In some implementations, the collimator 330 can be a collimating film capable of collimating light on-axis. The collimator 330 can include a stack of films such as, without limitations, reflective films, diffusion films, turning films, and prismatic films (such as brightness enhancing films). In some implementations, the collimator 330 can include cross-collimators, that is, at least two prismatic films arranged such that their respective prism axes are non-parallel (or in some implementations, orthogonal). In some implementations, collimator 330 can include lenses for further collimating and directing light towards the front of the display at a narrow angle of incidence. In some implementations, the collimator 330 is arranged between the color conversion material and the reflective aperture layer 340. In some implementations, the display module 300a does not include a collimator 330.

The display module 300a includes a rear light blocking layer 340 including a plurality of apertures 341 formed through light blocking portions 342. The rear light blocking layer 340 is capable of blocking substantially all light impinging on the rear side of the respective light blocking portions 342. In some implementations, the rear light blocking layer 340 includes a rear-facing reflective film capable of reflecting incident light on the light blocking portions 342. In some implementations, the rear light blocking layer 340 also includes a light absorbing material deposited over the reflective film to absorb light incident on the front facing surface of the rear light blocking layer 340. The rear light blocking layer 340 includes an aperture 341 for each subfield color (such as R, G and B) for each pixel 390. For each pixel 390, the respective apertures 341 are filled (or coated) with color-selective reflectors 345-347 associated with each subfield color. In some implementations, the color-selective reflectors 345-347 can be arranged in a way to spatially overlap with (but not necessarily fill) the apertures 341. The color-selective reflector 345 (the “red-pass color selective reflector”) is configured to pass red light 302. The color-selective reflector 346 (the “green-pass color selective reflector”) is configured to pass green light 303. The color-selective reflector 347 (the “blue-pass color selective reflector”) is configured to pass blue light 304. The color-selective reflectors are configured to reflect light of colors which they do not allow to pass. In some implementations, the color-selective reflectors 345-347 include distributed Bragg reflectors. In some other implementations, the color-selective reflectors 345-347 include cholesteric liquid crystals. In some other implementations, the color-selective reflectors 345-347 include 2-D arrays of nano-pillars formed, for example, from silver. The transmittance of some color-selective reflectors 345-357 can vary based on the angle of incident light. The collimation of light by the collimator 330 can help mitigate the variation of transmittance of such color-selective reflectors 345-347. Other color-selective reflectors 345-347, such as photonic crystals or the two-dimensional silver or aluminum nano-pillar arrays mentioned above exhibit none or minimal transmittance variation due to incidence angle.

The light modulation layer 350 includes a plurality of light modulators. The light modulators can be disposed on a substrate associated with the light modulation layer 350. Alternatively, the light modulators can be formed on the front substrate layer 360. In some implementations, a single light modulator is associated with each pixel 390. In some other implementations, multiple light modulators are associated with each pixel 390. For instance, in each pixel 390, a separate light modulator can be associated with each of the color-selective reflectors 345-347. The light modulators are capable of modulating light 302-305 passing through the color-selective reflectors 345-347. The controller 134 (shown in FIG. 1B) is configured to control the light modulator(s) in each pixel 390 to adjust the pixel illumination over time. Suitable light modulators include, without limitation, liquid crystal display modulators and micro-electromechanical system (MEMS) shutter-based modulators.

The front aperture layer 360 includes a plurality of apertures 361. Each aperture 361 is associated (or aligned) with a respective aperture 341 in the rear light blocking layer 340. Light passing through the rear aperture layer 340 and the light modulation layer 350 is output from the display module 300a through the apertures 361 and the front substrate layer 370 to form an image.

The light 306-308 reflected back from the color-selective reflectors 345-347 or light reflected back from the light blocking portions 342 of the rear light blocking layer 340 can be directed back to the light guide 310. Such light may be redirected back towards other pixels 390 or sub-pixels. For instance, green light reflected from the red-pass color-selective reflectors 345 or the blue-pass color-selective reflectors 347 may reflect back from the light guide 310 and manage to pass through a green-pass color-selective reflector 346 associated with a pixel 390 in a green illumination state. Similarly, red light reflected from the green-pass color-selective reflectors 346 or the blue-pass color-selective reflectors 347 may reflect back from the light guide 310 and manage to pass through a red-pass color-selective reflector 345 associated with a pixel 390 in a red illumination state. Reflecting blocked light back to the light guide 310 for use to illuminate other pixels 390 or sub-pixels is referred to herein as light recycling. Light recycling can improve the optical efficiency of the display module 300a by using light that would have been otherwise absorbed within a given pixel 390 to illuminate other pixels 390 or sub-pixels.

FIG. 3B shows a cross-sectional view of an example display module 300b incorporating a color conversion material packaged with a substantially monochromatic light source and color selective reflectors. The display module 300b includes a color conversion material 325 packaged with a substantially monochromatic light source 311, a light guide 310 having a reflective layer 312, a collimator 330, a rear light blocking layer 340, a light modulating layer 350, a front aperture layer 360, and a front substrate layer 370. The display module 300b also includes a plurality of pixels 390 distributed across the rear aperture layer 340, the light modulation layer 350, and the front aperture layer 360.

The display module 300b is similar to the display module 300a except that the color conversion material 325 is packaged with the substantially monochromatic light source 311, whereas the color conversion material 320 (in the display module 300a) is structured as a layer arranged across all (or a portion of) the pixels 390 of the display module 300a. The substantially monochromatic light source 311 (in the display module 300b) can be a substantially monochromatic light emitting diode (LED) die, a laser, or any other substantially monochromatic light source known to a person of ordinary skill in the art. The light source package 315 including the substantially monochromatic light source 311 and the color conversion material packaged therewith is capable of emitting light associated with red (R), green (G), and blue (B) subfield colors 305 used by the display module 300b to output images.

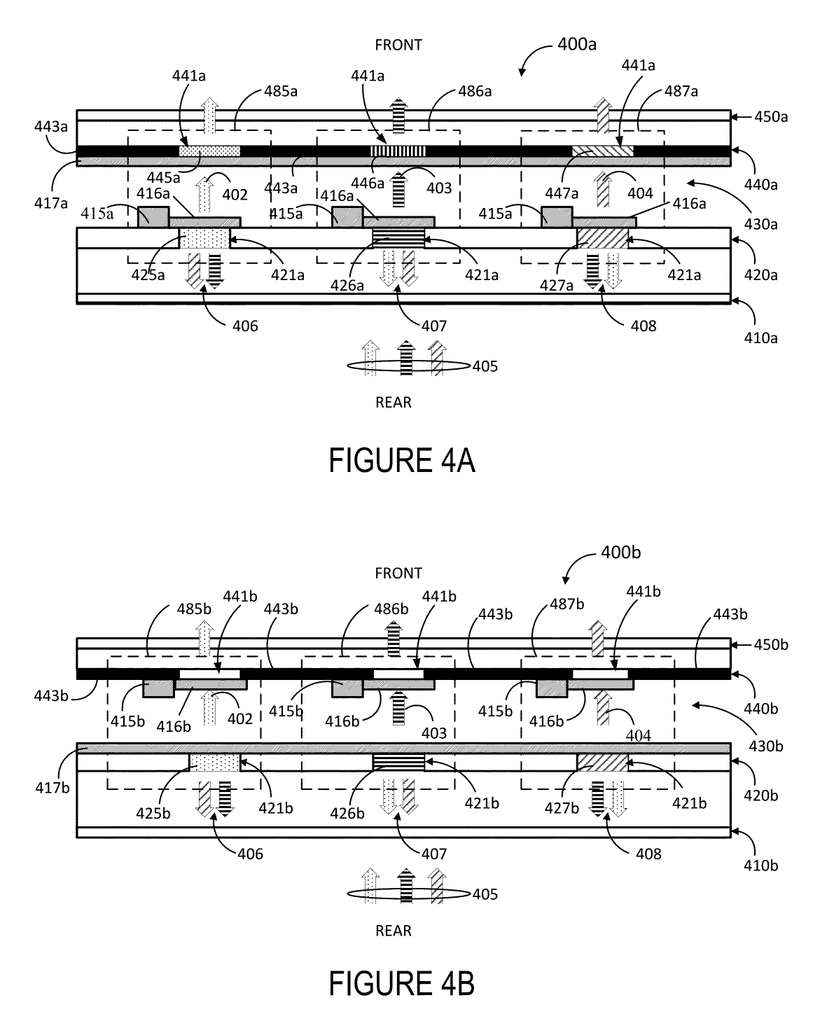

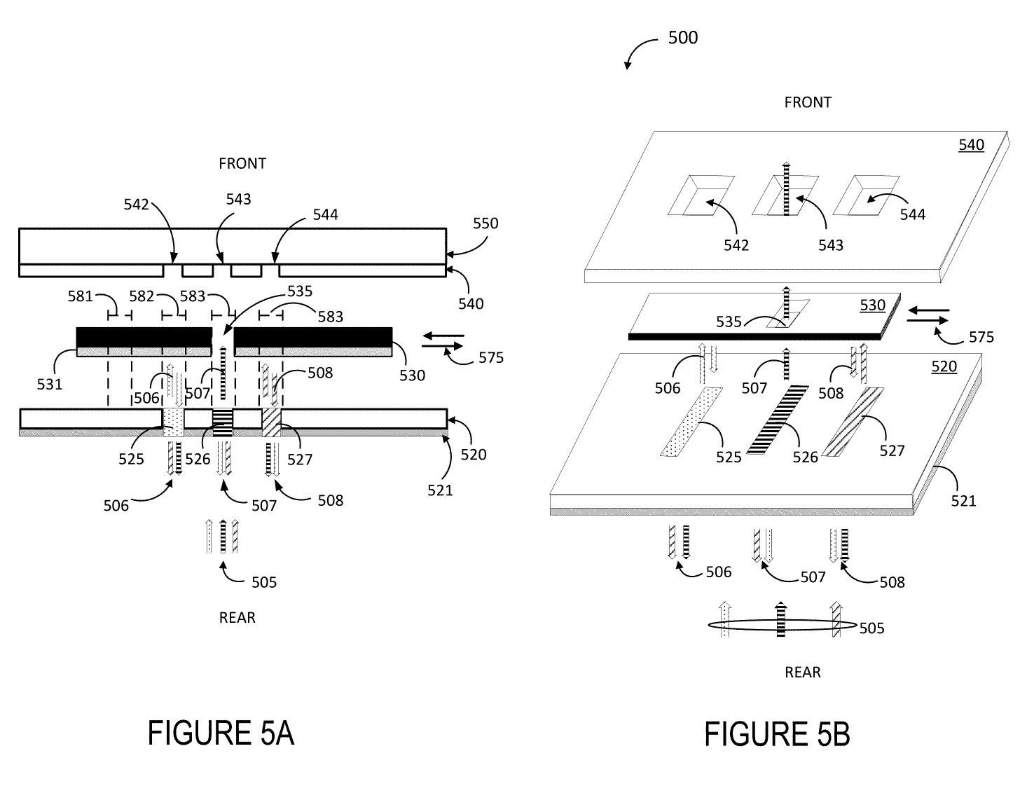

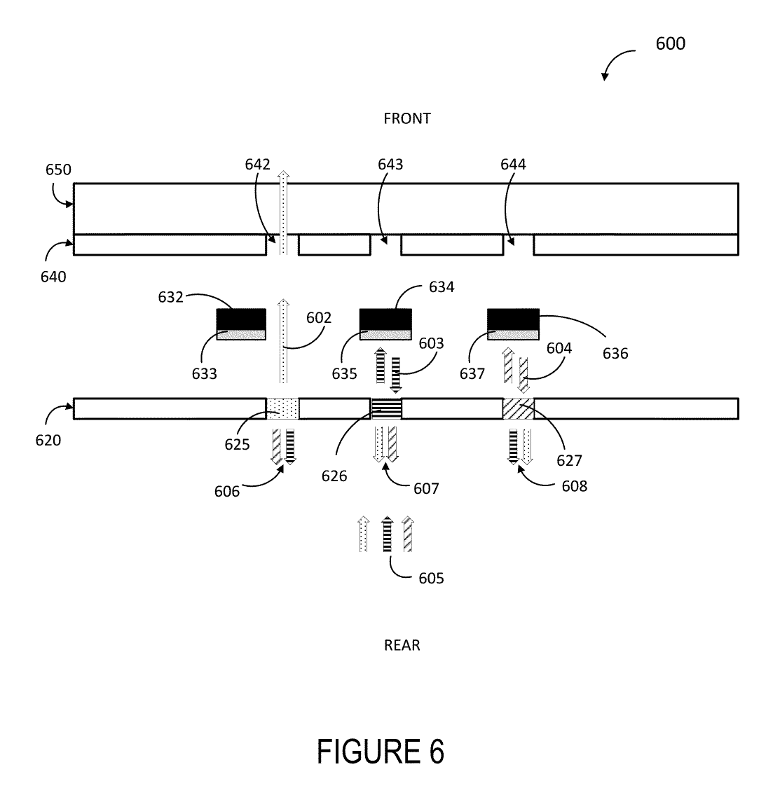

In the following, different implementations of the pixels 390 shown in FIGS. 3A and 3B are discussed in relation to FIGS. 4A, 4B, 5 and 6. FIGS. 4A and 4B show pixel implementations using liquid crystal light modulators, while FIGS. 5 and 6 show pixel implementations using electromechanical system (EMS) based light modulators such as micro-electromechanical system (MEMS) based light modulators.

FIG. 4A shows a simplified cross-sectional view of a pixel 400a of an example liquid crystal display (LCD) incorporating color conversion material and color selective reflectors 425a-427a. The pixel 400a includes a rear polarizer 410a, a rear light blocking layer 420a, a liquid crystal layer 430a, thin film transistors (TFTs) 415a, sub-pixel electrodes 416a, a common electrode 417a, a front light blocking layer 440a, and a front polarizer 450a.

The rear light blocking layer 420a includes three apertures 421a within the pixel 400a filled (or coated) with corresponding color-selective reflectors 425a-427a. As with the rear light blocking layer 340 shown in FIGS. 3A and 3B, the rear light blocking layer 420a can include a rear facing reflective layer and a front-facing light absorbing layer. The reflective layer can be formed from a light reflecting metal, such as, aluminum (Al), or by a stack of dielectric materials having alternating indices of refraction forming a dielectric mirror. In some implementations, the reflective layer can include both a metal layer and a stack of dielectric layers. The light absorbing material can be formed from a dark metal or by a resin in which light absorbing particles are suspended. In some implementations, the color-selective reflectors 425a-427a are deposited and patterned prior to the formation of the TFTs 415a and the sub-pixel electrodes 416a (such as shown in FIG. 4A). In some other implementations, the color-selective reflectors 425a-427a are deposited and patterned after the TFTs 415a and the sub-pixel electrodes 416a are formed.

The front light blocking layer 440a includes three apertures 441a (one for each subfield/sub-pixel color) per pixel. The apertures 441a within the pixel 400a are filled (or coated) with corresponding color filters 445a-447a. The color filters 445a-447a are selected to pass the color of the light passed by the respective color-selective reflectors 415a-417a opposite the color filters 445a-447a. The pixel 400a includes three sub-pixels; a red sub-pixel 485a, a green sub-pixel 486a, and a blue sub-pixel 487a. Each of the sub-pixels 485a-487a is capable of outputting a respective subfield color (such as red, green or blue).

FIG. 4B shows a simplified cross-sectional view of a pixel 400b of another example liquid crystal display (LCD) incorporating color conversion material and color selective reflectors 425b-427b. The pixel 400b includes a rear polarizer 410b, a rear light blocking layer 420b, a liquid crystal layer 430b, thin film transistors (TFTs) 415b, sub-pixel electrodes 416b, a common electrode 417b, a front light blocking layer 440b, and a front polarizer 450b.

The rear light blocking layer 420b includes three apertures 421b within the pixel 400b filled (or coated) with corresponding color-selective reflectors 425b-427b. As with the rear light blocking layer 420a shown in FIG. 4A, the rear light blocking layer 420b can include a rear facing reflective layer and a front-facing light absorbing layer. The reflective layer can be formed from a light reflecting metal, such as, Al, or by a stack of dielectric materials having attenuating indices of refraction forming a dielectric mirror. In some implementations, the reflective layer can include both a metal layer and a stack of dielectric layers. The light absorbing material can be formed from a dark metal or by a resin in which light absorbing particles are suspended. In some implementations, the color-selective reflectors 425b-427b are deposited and patterned prior to the formation of the common electrode 417b (such as shown in FIG. 4B). In some other implementations, the color-selective reflectors 425b-427b are deposited and patterned after the common electrode 417b.

The front light blocking layer 440b includes three apertures 441b (one for each subfield/pixel color) per pixel. Each of the apertures 441b is spatially aligned with a respective color-selective reflector (425b, 426b, or 427b). The TFTs 415b and the sub-pixel electrodes 416b are deposited behind the front light blocking layer 440b. The pixel 400b includes three sub-pixels; a red sub-pixel 485b, a green sub-pixel 486b, and a blue sub-pixel 487b. Each of the sub-pixels 485b-487b is capable of outputting a respective subfield color (such as red, green or blue).

Referring to FIGS. 4A and 4B, the pixels 400a and 400b are configured to modulate light 405 to form an image. The light 405 corresponds to light exiting a color conversion material, such as the color conversion material 320 and 325 shown in FIGS. 3A and 3B. As such, the light 405 is generally white in color having relatively sharp spectral peaks at the colors of the subfields used by the display including the pixels 400a or 400b. Light 405 (from the color conversion material) is polarized by the rear polarizer 410b. As the polarized light impinges on the rear light blocking layer 410a (or 410b) at the red sub-pixel 485a (or 485b), red light 402 passes into the liquid crystal layer 430a (or 430b) through the red-pass color-selective reflector 425a (or 425b). At the green sub-pixel 486a (or 486b), green light 403 passes into the liquid crystal layer 430a (or 430b) through the green-pass color-selective reflector 426a (or 426b). At the blue sub-pixel 487a (or 487b), blue light 404 passes into the liquid crystal layer 430a (or 430b) through the blue-pass color-selective reflector 426a (or 426b). Light not passing through the color-selective reflectors 425a-427a (or 425b-427b) is reflected back towards the rear of the display including the pixel 400a or 400b. The controller 134 (shown in FIG. 1B) causes a voltage to be applied to the respective sub-pixel electrodes. The voltage applied to each respective sub-pixel electrode is proportional (or inversely proportional) to the intensity of light desired to be output through the respective sub-pixel. The electric field across the liquid crystal resulting from the applied voltages alters the alignment of the liquid crystal molecules between the sub-pixel electrode 416a (or 416b) and the common electrode 417a (or 417b). The alignment change alters the polarity of light passing through the sub-pixel thereby altering the amount of light that will pass through the front polarizer 450a (or 450b) at the sub-pixel.

At the pixel 400a, each of the sub-pixels 485a-487a includes a respective color filter 445a, 446a, or 447a capable of filtering the light 402, 403, or 404 passing through the liquid crystal layer 430a. In some implementations, the color filters 445a-447a ensure the purity of the colors output at each sub-pixel. For example, the red-pass color filter 445a absorbs non-red light impinging on it, for example, light passing through the green-pass color-selective reflector 426a at an off-axis angle.

The use of the color filters 445a-447a, however, is optional. For instance, the pixel 400b shown in FIG. 4B does not include color filters, and the light 402, 403, or 404 passing through the color-selective reflectors 425b, 426b, or 427b, respectively, passes through the apertures 441b to illuminate the pixel 400b without further color filtering. In some implementations, color filters are not employed if the color-selective reflectors 425a-427a (or 425b-427b) have narrow transmission bands.

FIG. 5A shows a two-dimensional (2-D) cross-sectional view of an example MEMS-based display pixel 500 incorporating color-selective reflectors 525-527. FIG. 5B shows a three-dimensional (3-D) representation of the MEMS-based display pixel 500. The pixel 500 includes a rear light blocking layer 520 including three color-selective reflectors 525527, a shutter 530 (similar to the shutter assembly 200 shown in FIGS. 2A and 2B) having a single shutter aperture 335, a front light blocking layer 540, and a front substrate layer 550. In some implementations, the rear light blocking layer 520 includes a rear-facing reflective film 521 capable of reflecting back incident light. The pixel 500 is configured to modulate light 505 to form an image. The light 505 corresponds to light exiting a color conversion material, such as the color conversion material 320 and 325 shown in FIGS. 3A and 3B. As such, the light 505 is generally white in color having relatively sharp spectral peaks at the colors of the subfields used by the display including the pixel 500.

In some implementations, the front light blocking layer 540 includes three apertures 542-544 spatially aligned, respectively, with the positions 582-584. In some implementations, the apertures 542-544 may be filled or coated, respectively, with red, green and blue color filters. In some other implementations, no color filters are employed.

As the light 505 impinges on the reflective aperture layer 520, the red-pass color-selective reflector 525 passes red light. The green-pass color-selective reflector 526 passes green light 503. The blue-pass color-selective reflector 527 passes green light. Non-red light 506, non-green light 507, and non-blue light 508 are reflected back by the red-pass color-selective reflector 525, the green-pass color-selective reflector 526, and the blue-pass color selective reflector 527, respectively.

The shutter 530 includes a single shutter aperture 535 and is configured to move in the directions indicated by the arrows 575. The shutter is configured to move between four different positions associated with four positions 581-584 of the shutter aperture 535. When the shutter aperture 535 is at a first position 581, all the light 506-508 passing through the color selective reflectors 525-527 is blocked by the shutter 530. In some implementations, the shutter 530 includes a rear-facing reflective film 531 capable of reflecting back light incident thereon. Such light can pass back through the color-selective reflectors 525-527 to be redirected in the display backlight back towards other pixels through which the light may pass. When the shutter aperture 535 is at the first position 581, the pixel 500 is in a black illumination state with no light output through the pixel. At a second position 582, the shutter aperture 535 is aligned with the red-pass color-selective reflector 525 and the pixel 500 is in a red illumination state with red light 506 passing through the shutter aperture 535 and a corresponding aperture 542 in the front light blocking layer 540. At a third position 583, the shutter aperture 535 is aligned with the green-color color-selective reflector 526 and the pixel 500 is in a green illumination state with green light 507 passing through the shutter aperture 535 and a corresponding aperture 543 in the front light blocking layer 540. At a fourth position 584, the shutter aperture 535 is aligned with the blue-pass color-selective reflector 527 and the pixel 500 is in a blue illumination state with blue light 508 passing through the shutter aperture 535 and a corresponding aperture 544 in the front light blocking layer 540. In each of the second-fifth positions, light passing through the color-selective reflectors 525-527 and not passing through the shutter aperture 535 may be reflected back towards the color-selective reflectors 525-527 into the backlight to be recycled.

A display incorporating the pixel 500 can be operational according to a field sequential color (FSC) image formation process. In such a process, a controller controls each pixel to alternately modulate each subfield color. For example, for a given image frame, the controller would cause the pixel to output image data for one or more red subframes by causing the shutter 530 to move between the first and second positions 581 and 582. The controller would also cause the pixel to output image data for one or more green subframes by causing the shutter 530 to move into the first or third position (581 or 583) for each green subframe, and so forth.

FIG. 6 shows a cross sectional view of another example MEMS-based display pixel 600 incorporating color-selective reflectors 625-627. The pixel 600 includes a rear light blocking layer 620 including the three color-selective reflectors 625627, three shutters 632, 634, and 636, and a front light blocking layer 640 on a front substrate 650. The pixel can be configured to modulate white light 606 leaving a color conversion material similar to the color conversion material 320 and 325 shown in FIGS. 3A and 3B.

In some implementations, the shutters 632, 634, and 636 can be parts of shutter assemblies similar to the shutter assemblies 200 shown in Figured 2A and 2B. The 632, 634, and 636 also can include, respectively, rear-facing reflective films 633, 635, and 637 capable of reflecting back light incident on their rear facing surfaces.

The rear light blocking layer 620 can be similar to the rear light blocking layer 520 shown in FIGS. 5A and 5B.

The light 605 impinges on the rear light blocking layer 620 and is blocked (or reflected back) at light blocking portions of the rear light blocking layer 620. The red-pass color-selective reflector 625 passes red light 602. The green-pass color-selective reflector 626 passes green light 603. The blue-pass color-selective reflector 627 passes blue light 604. Light reflected back by the color selective reflectors 625-627 is directed back towards the backlight of the display for recycling.

In some implementations, the front light blocking layer 640 includes three apertures 642-644 spatially aligned with the color-selective reflectors 625-627, respectively. In some implementations, the apertures 642-644 may be filled or coated, respectively, with red, green and blue color filters. In some other implementations, no color filters are employed.

The shutters 632,634, and 636 are associated with the color-selective reflectors 625-627, respectively. That is, the shutter 632 is configured to selectively pass or block light 602 emerging from the red-pass color-selective reflector 625, the shutter 634 is configured to selectively pass or block light 603 emerging from the green-pass color-selective reflector 626, and the shutter 636 is configured to selectively pass or block light 604 emerging from the blue-pass color-selective reflector 627. Each of the shutters 632,634, and 636 has two positions, an open position and a closed position. The shutter 632 is shown in an open state allowing the light 602 to pass towards the front light blocking layer 640. In the closed state, the shutter 632 would be spatially aligned with the color-selective reflector 625, therefore, blocking the light 602. The shutters 634 and 636 are shown in closed states blocking the light 603 and 604, respectively, from passing towards the front light blocking layer 640 and out of the display. In the open states, the shutters 634 and 636 would not block the light 603 and 604 from passing towards the front of the pixel 600 (for instance, towards the apertures 643 and 644, respectively).

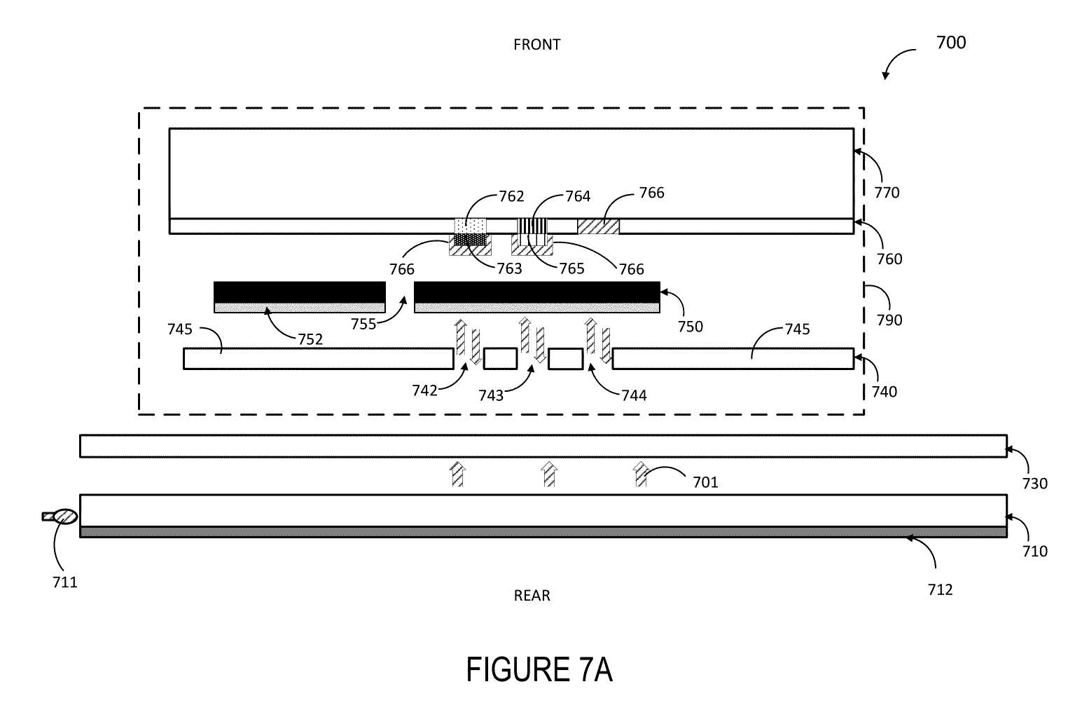

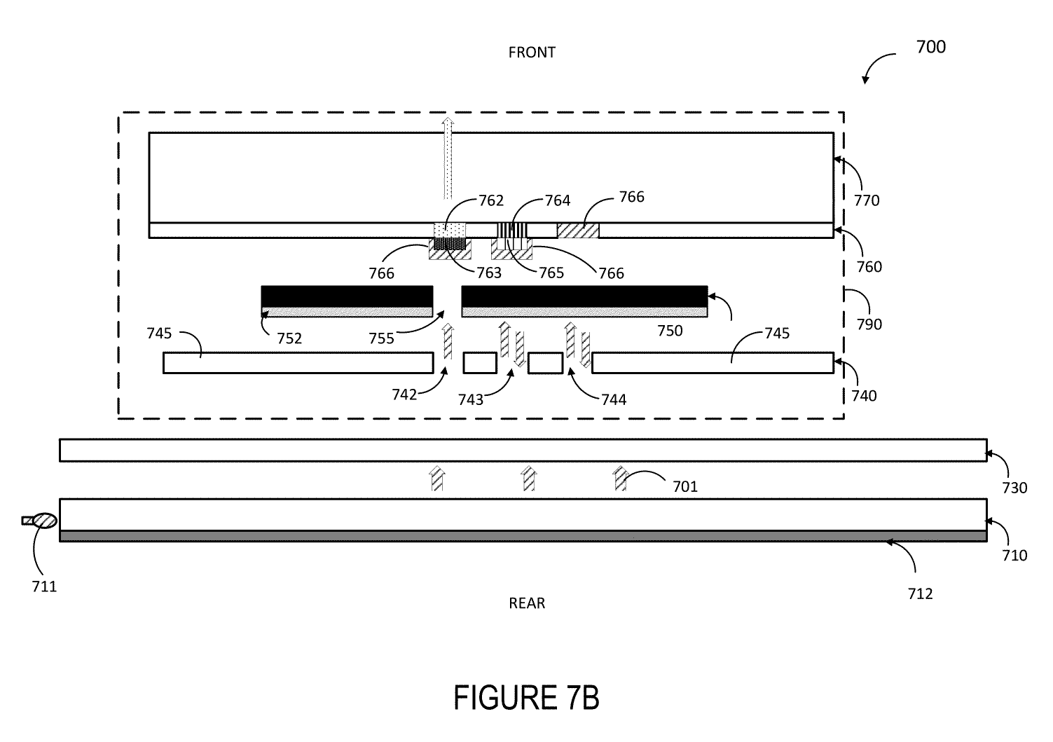

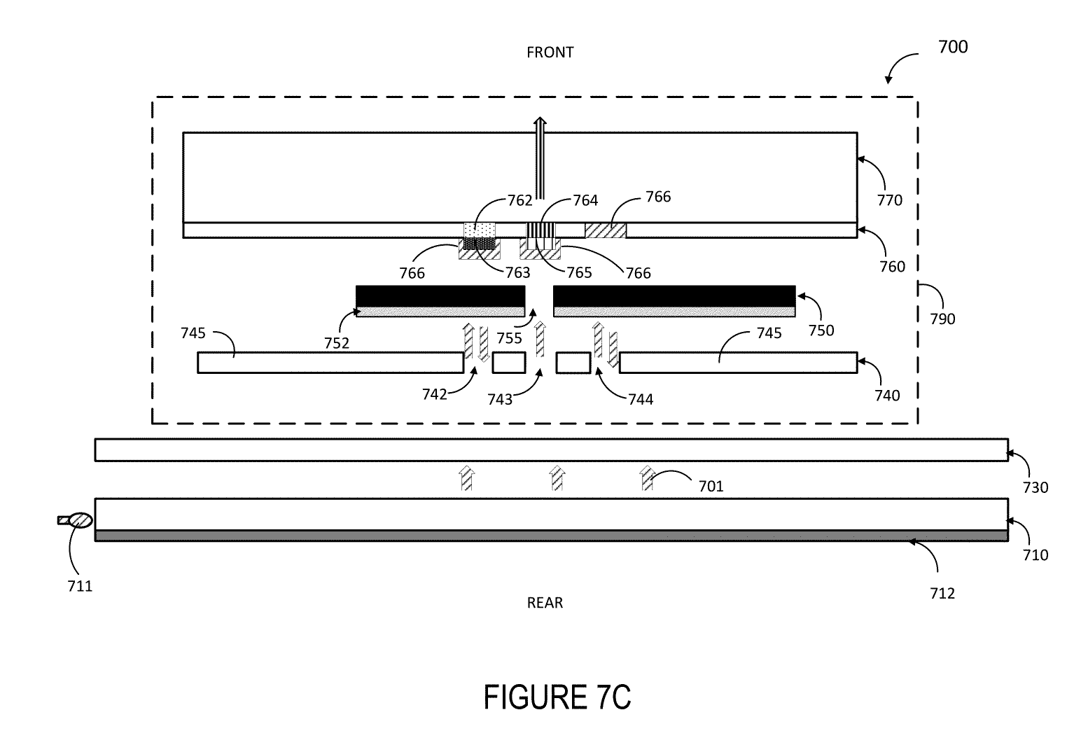

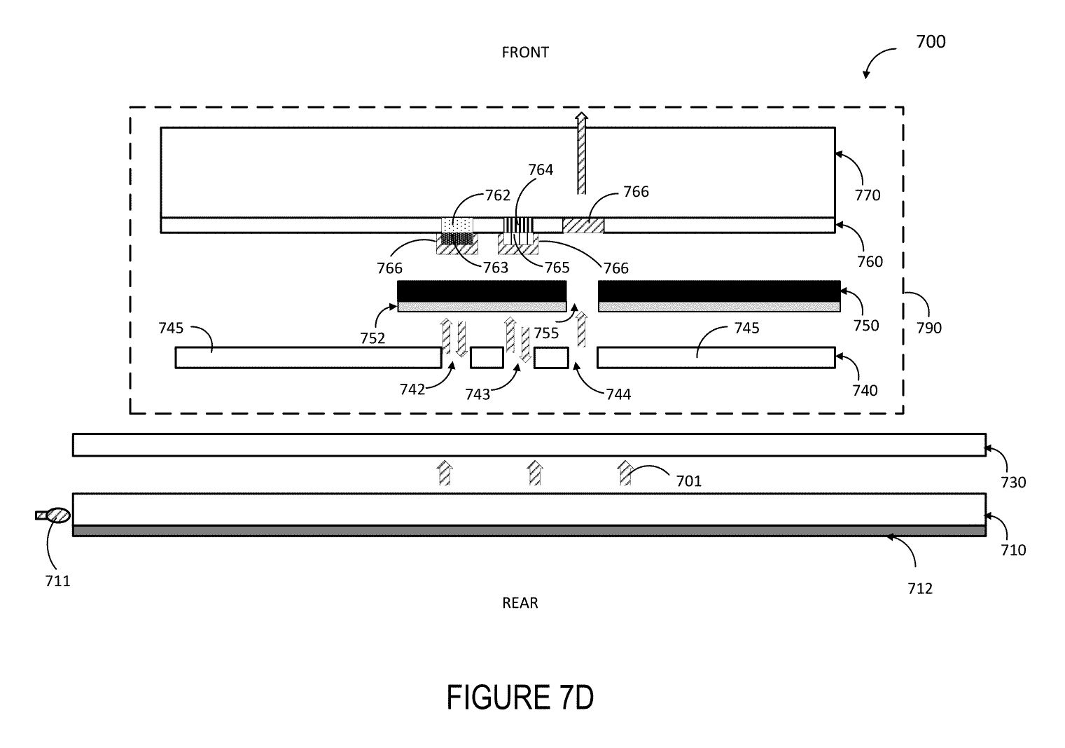

FIGS. 7A-7D show cross-sectional views of an example MEMS based display module 700 incorporating color conversion material 763 and 765 and color-selective reflectors 762,764, and 766. The display module 700 includes a substantially monochromatic light source 711, a light guide 710 adjacent to a front-facing reflective layer 712, a collimator 730, a rear light blocking layer 740, a shutter 750 (such as the shutter assembly 200 shown in FIGS. 2A and 2B), and a front light blocking layer 760 on a front substrate 770. In the FIGS. 7A-7D, only a single shutter 750 and portions of the rear aperture layer 740 and the front light blocking layer 760 associated with a single pixel 790 are shown for the sake of illustration. A person of ordinary skill in the art should appreciate that the display module includes a plurality of pixels arranged across the light guide 710 and the collimator 730. With respect to the pixel 700, the FIGS. 7A-7D illustrate different illumination states of the pixel 790.

The substantially monochromatic light source 711, the light guide 710, and the collimator 730 are similar to the substantially monochromatic light source 311, light guide 310, and collimator 330 shown in FIGS. 3A and 3B. The substantially monochromatic light source 711 is capable of emitting substantially monochromatic light 701. The substantially monochromatic light 701 is selected in this implementation to be blue. The substantially monochromatic light 701 is distributed across the display by the light guide 710.

In the pixel 790, the rear light blocking layer 740 includes three apertures 742-744 one for each subfield color employed by the display module 700. The real light blocking layer apertures 742-744 are defined through light blocking portions 745 of the rear light blocking layer 740. The light blocking portions 745 are capable of reflecting light incident on the rear facing surface of the light blocking portions 745, and in some implementations, absorbing light incident on the front facing surfaces of the rear light blocking portions 745. In some implementations, the light blocking portions 745 may include a rear-facing reflective film (similar to the reflective film 521 shown in FIG. 5) capable of reflecting incident light back towards the light guide the light guide 710.

The shutter 750 can be part of a shutter assembly similar to that shown in FIGS. 2A and 2B. The shutter 750, though, includes only a single shutter aperture 755. In some implementations, the shutter 750 includes a rear-facing reflective film 752 capable of reflecting back light 701 passing through the apertures 742-744 that does not pass through the shutter aperture 755.

The front light blocking layer 760 includes a blue-pass color-selective reflector 766 capable of passing blue light and reflecting back light associated with other colors. In some implementations, the blue-pass color-selective reflector 766 extends across the rear surface of substantially the entire front light blocking layer 760. In some other implementations, the blue-pass color-selective reflector 766 is patterned such that it is present substantially in areas on the front light blocking layer 760 that spatially overlap with the apertures 742-744 (as shown in FIGS. 7A-7D) or, in some implementations, just over the apertures 743 and 744. The front light blocking layer 760 also includes two color conversion materials; a red color conversion material 763 and a green color conversion material 765 capable of converting the substantially monochromatic light 701 into red and green light, respectively. A red-pass color selective reflector 762 similar to the red-pass color-selective reflectors 525 shown in FIG. 5 is positioned in front of the color conversion material 763. A green-pass color selective reflector 764 similar to green-pass color selective reflector 526 shown in FIG. 5 is positioned in front of the color conversion material 765. The red-pass color-selective reflector 762 and the red-pass color conversion material 763 are arranged to spatially overlap with the aperture 742. The green-pass color-selective reflector 764 and the green-pass color conversion material 765 are arranged to spatially overlap with the aperture 742.

Referring to FIG. 7A, the shutter 750 is shown in a closed position in which the shutter aperture 755 does not align with any of the apertures 742-744. As such, all the substantially monochromatic light 701 passing through the apertures 742-744 is blocked from passing towards the front light blocking layer 760. With the shutter 750 in the closed position, the pixel 790 is in a black state with no light being output from the pixel 790. In some implementations, light incident on the rear surface of the shutter 750 can be reflected back through the apertures 742-744 and be recycled to illuminate other pixels or sub-pixels of the display module 700

Referring to FIG. 7B, the pixel 790 is in a red illumination state. The shutter 750 is in a second position in which the shutter aperture 755 is aligned with the aperture 742. As such, the substantially monochromatic light 701 passing through the aperture 742 passes through the shutter aperture 755 and the blue-pass color-selective reflector 766 into the color conversion material 763. The blue-pass color-selective reflector 766 can reflect back a portion of the substantially monochromatic light 701 depending on the transmission spectrum of the blue-pass color-selective reflector 766 and the purity of the substantially monochromatic light 701. The red color conversion material 763 converts the incident substantially monochromatic light 701 into red light which it emits in all directions. The red light emerging from the red color conversion material 763 impinges on the red-pass color-selective reflector 762. The red light passes through the red-pass color-selective reflector 762 and is output by the pixel 790. Red light impinging on the blue-pass color-selective reflector 766 is reflected back towards the red-pass color-selective reflector 762 for passage out of the display. The substantially monochromatic light 701 passing through the apertures 743 and 744 is reflected by the shutter 750 back towards the light guide 710. The reflected light can be recycled to illuminate other pixels of the display module 700.

Referring to FIG. 7C, the pixel 790 is in a green illumination state. The shutter 750 is in a third position in which the shutter aperture 755 is aligned with the aperture 743. As such, the substantially monochromatic light 701 passing through the apertures 742 and 744 is reflected back by the shutter 750 towards the light guide 710 while the substantially monochromatic light passing through the aperture 743 passes through the shutter aperture 755 and the blue-pass color-selective reflector 766 into the color conversion material 765. The color conversion material 765 converts the incident substantially monochromatic light 701 into red light which it emits in all directions. The green light passes through the green-pass color-selective reflector 764 and is output by the pixel 790. Green light impinging on the blue-pass color-selective reflector 766 is reflected back towards the green-pass color-selective reflector 764 for passage out of the display 700. The light reflected by the shutter 750 can be recycled to illuminate other pixels of the display module 700.

Referring to FIG. 7D, the pixel 790 shown therein is in a blue illumination state. The shutter 750 is in a fourth position in which the shutter aperture 755 is aligned with the aperture 744. As such, the substantially monochromatic light 701 passing through the apertures 742 and 743 is reflected back by the shutter 750 towards the light guide 710 while the substantially monochromatic light passing through the aperture 744 passes through the shutter aperture 755 and the blue-pass color-selective reflector 766. The blue light passes through the blue-pass color-selective reflector 766 and is output by the pixel 790. Light reflected back by the shutter 750 can be recycled to illuminate other pixels of the display module 700.

The display incorporating 700 can be operated according to a field sequential color (FSC) image formation process. In such a process, a controller (such as the controller 134 shown in FIG. 1B) controls each pixel 790 to alternately modulate each subfield color. For example, for a given image frame, the controller would cause the pixel 790 to output image data for one or more red subframes by causing the shutter 750 to move between the first and second positions. The controller would also cause the pixel to output image data for one or more green subframes by causing the shutter 750 to move into the first or third position for each green subframe, and so forth.

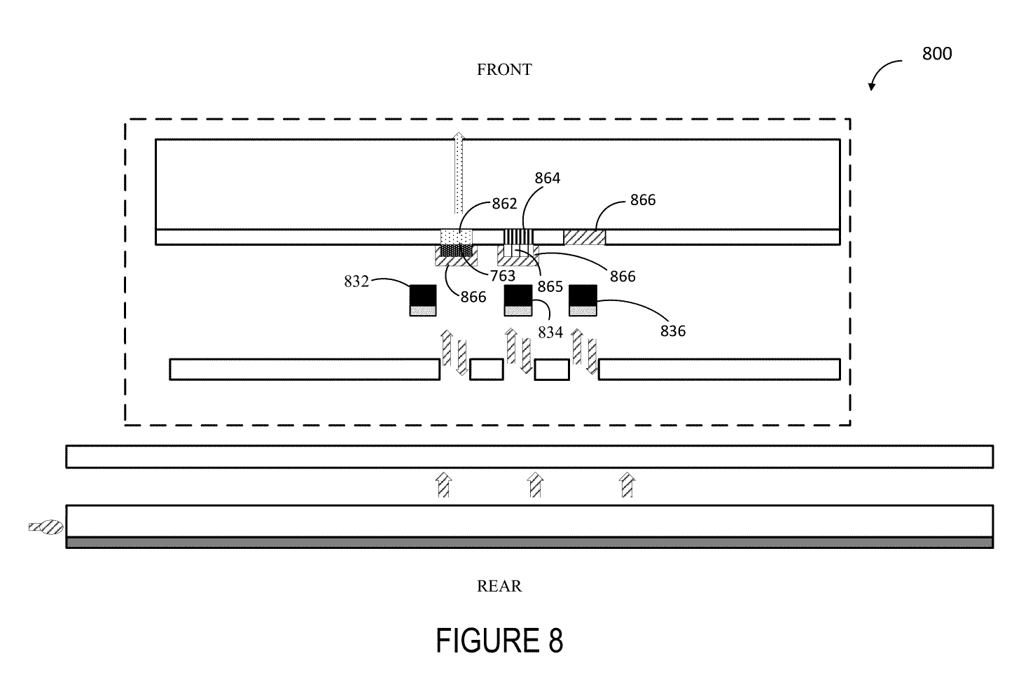

FIG. 8 shows a cross-sectional view of another example MEMS based display module 800 incorporating color conversion material 863 and 865 and color selective reflectors 862, 864, and 866. The display module 800 is similar to the display module 700 shown in FIGS. 7A-7D, except that in the display module 800 each pixel 890 has three shutters 832, 834, and 836 (similar to shutter 632, 634, and 636 shown in FIG. 6). Each of the shutters 832, 834, and 836 has two positions; one associated with an open state and another associated with a closed state. The controller 134 (shown in FIG. 1B) can control the shutters 832, 834, and 836 and cause each shutter to transition between the open and closed states. As shown in FIG. 8, the shutter 832 is in the open state whereas the shutters 834 and 836 are in the closed state.

The use of multiple shutters (as shown in FIGS. 6 and 8) per pixel allows for the pixel to output image data for more than one color subfield simultaneously.

While the implementations discussed in relation to FIGS. 3A-8 include color selective reflectors associated with the red, green, and blue colors, other color-selective reflectors associated with other colors such as yellow, cyan, magenta, or other colors be employed. Also, depending on the implementations, color conversion material for converting substantially monochromatic light into yellow, cyan, magenta, or other colors may be used.

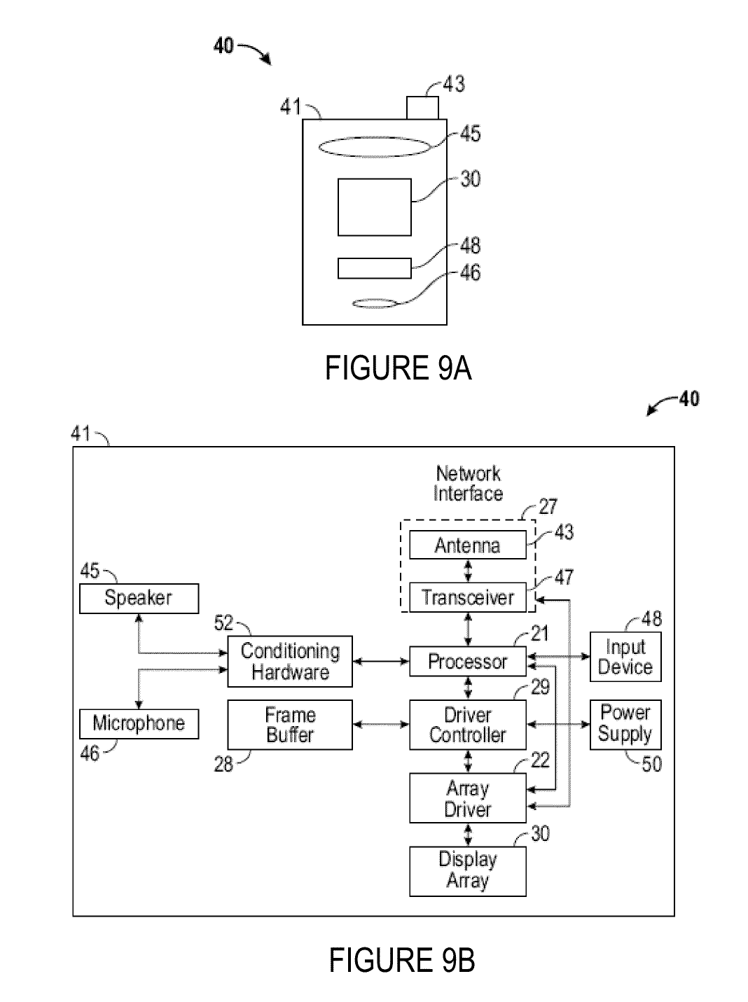

FIGS. 9A and 9B show system block diagrams of an example display device 40 that includes a plurality of display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be capable of including a flat-panel display, such as plasma, electroluminescent (EL) displays, OLED, super twisted nematic (STN) display, LCD, or thin-film transistor (TFT) LCD, or a non-flat-panel display, such as a cathode ray tube (CRT) or other tube device. In addition, the display 30 can include a mechanical light modulator-based display, as described herein.

The components of the display device 40 are schematically illustrated in FIG. 9B. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 9A, can be capable of functioning as a memory device and be capable of communicating with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to any of the IEEE 16.11 standards, or any of the IEEE 802.11 standards. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G, or further implementations thereof, technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29 is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements. In some implementations, the array driver 22 and the display array 30 are a part of a display module. In some implementations, the driver controller 29, the array driver 22, and the display array 30 are a part of the display module.

In some implementations, the driver controller 29, the array driver 22, and the display array 30 are appropriate for any of the types of displays described herein. For example, the driver controller 29 can be a conventional display controller or a bi-stable display controller (such as a mechanical light modulator display element controller). Additionally, the array driver 22 can be a conventional driver or a bi-stable display driver (such as a mechanical light modulator display element controller). Moreover, the display array 30 can be a conventional display array or a bi-stable display array (such as a display including an array of mechanical light modulator display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40. Additionally, in some implementations, voice commands can be used for controlling display parameters and settings.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The processes of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of any device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A display apparatus comprising:
a substantially monochromatic light source capable of outputting substantially monochromatic light;
a color conversion material capable of converting at least a portion of the substantially monochromatic light output by the substantially monochromatic light source into light associated with at least one subfield color; and
a plurality of pixels, each pixel including at least two color-selective reflectors, each color-selective reflector being capable of passing light of a respective subfield color and reflecting light associated with at least two other subfield colors.

2. The display apparatus of claim 1, wherein the substantially monochromatic light source has a wavelength range with a full width at half maximum (FWHM) less than or equal to 100 nanometers.

3. The display apparatus of claim 1, further including a collimator capable of collimating light directed at the color-selective reflectors.

4. The display apparatus of claim 1, further including a light guide capable of guiding light output by the substantially monochromatic light source towards the display elements.

5. The display apparatus of claim 1, wherein the color conversion material includes at least one of a quantum dot film or a phosphor film.

6. The display apparatus of claim 1, wherein the color-selective reflectors include distributed Bragg reflectors (DBRs) or cholesteric liquid crystals.

7. The display apparatus of claim 1, wherein the color-selective reflectors include a substantially angle invariant color selective reflector.

8. The display apparatus of claim 1, wherein the light output by the substantially monochromatic light source is a blue light or an ultra violet (UV) light.

9. The display apparatus of claim 1, wherein each pixel includes a respective light modulator.

10. The display apparatus of claim 8, wherein the light modulators are liquid crystal (LC) light modulators.

11. The display apparatus of claim 1, further including a light blocking layer positioned between the pixels and the color conversion material, wherein the light blocking layer defines a plurality of apertures and each of the color-selective reflectors associated with the pixels is positioned in an optical path between an aperture and a light modulator.

12. The display apparatus of claim 10, wherein each pixel further includes a color filter associated with a respective color-selective reflector.

13. The display apparatus of claim 8, wherein the light modulators include micro-electromechanical system (MEMS) shutters.

14. The display apparatus of claim 1, wherein each pixel further includes two other color-selective reflectors each being associated with a respective color conversion material.

15. The display apparatus of claim 12, wherein each light modulator includes multiple micro-electromechanical system (MEMS) shutters, each MEMS shutter being associated with a respective color-selective reflector.

16. A display apparatus comprising:
means for outputting substantially monochromatic light;
color conversion means for converting at least a portion of the substantially monochromatic light output by the substantially monochromatic light source into light associated with at least one subfield color; and
a plurality of pixels, each pixel including at least two color-selective reflecting means, each color-selective reflecting means being capable of passing light of a respective subfield color and reflecting light associated with at least two other subfield colors.

17. The display apparatus of claim 16, wherein the substantially monochromatic light has a full width at half maximum (FWHM) bandwidth of less than or equal to about 100 nanometers.

18. The display apparatus of claim 16, further comprising collimating means for collimating light directed at the color-selective reflectors.

19. The display apparatus of claim 16, wherein the color-selective reflective means include substantially angle invariant color-selective reflective means.

20. The display apparatus of claim 1, wherein the light output by the substantially monochromatic light source is a blue light or an ultra violet (UV) light.

21. The display apparatus of claim 16, wherein each pixel includes respective light modulating means.

22. The display apparatus of claim 16, further comprising light blocking means positioned between the pixels and the color conversion means, wherein the light blocking means define a plurality of apertures and each of the color-selective reflecting means associated with the pixels is positioned in an optical path between an aperture and the light modulating means.

23. The display apparatus of claim 21, wherein each pixel further includes color filtering means associated with respective color-selective reflecting means.

24. A method of displaying image data comprising:
generating, by a substantially monochromatic light source, substantially monochromatic light;
converting, by a color conversion material, at least a portion of the substantially monochromatic light into light associated with at least one subfield color; and
at each of a plurality of pixels, selectively passing light of a respective subfield color and reflecting light associated with at least two other subfield colors by at least two color-selective reflectors.

25. The method of claim 24 further comprising guiding the substantially monochromatic light towards display elements.

26. The method of claim 24, wherein the substantially monochromatic light has a full width at half maximum (FWHM) bandwidth of less than or equal to about 100 nanometers.

27. The method of claim 24, further comprising collimating light directed at the color-selective reflectors.

28. The method of claim 24, wherein the color of the light passed and reflected by the color selective reflectors is substantially independent of the angle at which the light is incident on the color selective reflectors.

29. The method of claim 24 further comprising modulating light associated with each pixel based on the image data.

30. The method of claim 24 further comprising color filtering, at each pixel, light associated with a respective color-selective reflector by a color filter.
